(19) United States
(12) Patent Application Publication
(10) Pub. No.: US 2025/0290192 A1
(43) Pub. Date: Sep. 18, 2025

(54) COATING PLANT AND METHOD FOR TARGET REPLACEMENT

(71) Applicant: SINGULUS TECHNOLOGIES AG, Kahl am Main (DE)

(72) Inventors: Andreas LUDWIG, Aschaffenburg (DE); Andreas RUPPEL, Butzbach (DE); Ralf HEILAND, Wiesbaden (DE)

(21) Appl. No.: 18/994,457

(22) PCT Filed: Jul. 5, 2023
(86) PCT No.: PCT/EP2023/068474

§ 371 Date: Jan. 14, 2025

(30) Foreign Application Priority Data
Jul. 21, 2022 (DE) 10 2022 002 669.4

(51) Int. Cl. C23C 14/34; C23C 14/35; H01J 37/34

(52) U.S. Cl. CPC C23C 14/3407; C23C 14/35; H01J 37/3417; H01J 37/3435; H01J 37/3441

(57) ABSTRACT

The present invention relates to a coating plant for coating substrates by means of sputtering as well as a process for replacing a target in such a coating plant.

The present invention relates to a coating plant for coating substrates by means of sputtering as well as to a process for replacing a target in such a coating plant.

When coating by means of cathode sputtering, the target material of the cathode has to be replaced in regular intervals due to the sputter process that takes place at the target. As a rule, the target as such cannot be removed since it is fixed to a so-called target backing plate or target support plate. Moreover, the target is usually surrounded by a dark space or a so-called dark space shield connected to ground. The target and the components surrounding it have, as a rule, a high weight and have to be mounted on a chamber element of the plant, for example, they are mounted in a hanging position on the chamber lid or on the chamber wall. However, operations beneath the cathode have to be avoided for safety reasons. In addition, it should be possible that the operation can be performed by a single person. In this context, it is desirable that access to the target and the components surrounding it as well as their assembly is easy. Industry demands a simple, fast and safe replacement process in order to keep plant downtimes of the plant as short as possible.

According to the solution commonly used today, the target backing plate is screwed against insulators mounted in the coating chamber. Subsequently, the dark space shield is set above the target backing plate and is fixed to the coating chamber using screws. Before it is definitively fixed, the dark space shield has to be aligned with respect to the target.

Examples of coating plants with replaceable targets are for example described in U.S. Pat. No. 6,494,999 B1, DE 197 32 002 A1, DE 4 133 564 A1, DE 25 13 216 A1, DE 22 53 879 A and DE 195 25 007 A1.

One object of the present invention is to provide a coating plant with a target construction allowing simple, fast and safe replacement of the target material. Said object is achieved by the coating plant of claim 1. Preferred embodiments of the coating plant of the invention are described in the dependent claims. The present invention is further directed to a method for replacing a target in such a coating plant.

Accordingly, the present invention is directed to a coating plant for coating of substrates by means of sputtering. The coating plant comprises at least a magnet system with one or more magnets, a dark space shield, a target and a target backing plate (or target support plate), wherein the dark space shield, the target and the target backing plate form a pre-assembled unit (without magnet system) which can be introduced into the coating plant (including the magnet system) and replaced as unit, with target and dark space shield being electrically insulated from each other. The coating plant further comprises a coupling mechanism that allows the pre-asssembled unit (without the magnet system) to be attached to the coating plant (including the magnet system). The coupling mechanism is fixed to the dark space shield or interacts with the dark space shield. Hereinafter, the combination of target and target backing plate is also referred to as “cathode”.

The pre-assembled unit consisting of dark space shield, target and target backing plate allows simple handling and safe mounting of the unit so that the replacement of the target material can be performed in the coating plant of the invention rapidly and without long plant downtimes.

Preferably, the coupling mechanism comprises one (or more) eccentric shaft(s). The eccentric shaft can be a tube or a round rod having one or more eccentrically formed inner sections, wherein at least one opening for receiving a coupling element is provided at each of the eccentrically formed inner sections. Preferably, the dark space shield or a section of the coating plant to which the pre-assembled unit can be attached comprises one or more coupling elements which are adapted to engage with the eccentric shaft, in particular with its opening(s). Preferably, a rotation of the eccentric shaft causes the unit consisting of dark space shield, target and target backing plate to be moved towards the magnet system and to be held in a defined position. In particular, a rotation of the eccentric shaft causes the unit of dark space shield, target and target backing plate to be clamped or braced against a section of the chamber, for example a chamber lid or a chamber wall.

The solution based on the eccentric shaft makes the handling of the pre-assembled unit even simpler and safer. In particular, with said solution, the coupling mechanism can be arranged in the processing area (i.e., the vacuum) so that no additional openings are required. The eccentric shaft can be driven directly and manually without the need for a motor or other components.

According to a particularly preferred embodiment of the coating plant of the invention, the pre-assembled unit of dark space shield, target and target backing plate further comprises positioning sleeves and/or clamping bolts. The pre-assembled unit can be moved to the coating plant, using for example an auxiliary device. Said auxiliary device is then guided over a stop, placed at the coating chamber where the pre-assembled unit is lifted. During the lifting process, two positioning pins, that are for example screwed to the chamber lid, enter the positioning sleeves of the pre-assembled unit and align it precisely in the coating chamber. Shortly before the lifting process is completed, the clamping bolts, which are mounted on the dark space shield, for example, engage in the eccentric shaft of the coupling mechanism. For example, four clamping bolts can engage in two eccentric shafts with milled eccentric recesses. By rotating the two eccentric shafts, the clamping bolts are clamped to the eccentric shafts. This causes the dark space shield to be clamped against a chamber element, e.g. the chamber lid or a chamber wall. Spring elements mounted on the dark space shield are pressed against the chamber lid when clamped and ensure a defined contact and equipotential bonding with respect to the chamber. One or more screws are used to ensure a defined contact between the power connection and the target backing plate as well as compression of the sealing rings. The auxiliary device can then be removed.

By providing a pre-assembled unit, the alignment between the target and the dark space shield can be carried out before service work at the coating plant at the workplace. This reduces the service time at the plant and enables a significant simplification and shortening of the service work, thereby increasing the production capacity of the plant.

Instead of the arrangement described above, an inverted structure would also be conceivable, in which the clamping bolts are mounted in the coating chamber and the eccentric shafts are attached to the dark space shield.

The pre-assembled unit of dark space shield, target and target backing plate preferably has a longitudinal extension, with the eccentric shaft extending along said longitudinal extension. This makes it easy to adapt the coating system of the invention to different target lengths.

The eccentric shaft preferably allows a maximum stroke of 10 mm at most, more preferably of 5 mm at most and particularly preferably of 2 mm at most. Preferably, the eccentric shaft can be directly manually rotated.

The coating plant preferably comprises a vacuum area which can be evacuated for the coating process, with the coupling mechanism being located entirely within the vacuum area. Preferably, the vacuum area has to be opened in order to allow manual operation of the coupling mechanism.

The magnet system can preferably be displaced with respect to the pre-assembled unit of dark space shield, target and target backing plate in three spatial directions and can optionally be tilted with respect to the pre-assembled unit. This allows the magnet system to be aligned specifically with the target.

Preferably, the coating plant further comprises a connecting section via which electric current and/or a coolant can be supplied into the pre-assembled unit of dark space shield, target and target backing. Preferably, at least one additional threaded connection is provided in the area of said connecting section. The opening for the connection media is preferably located outside the coating area. The media connection block is mounted on the chamber in an insulated position and is located in the area of the opening for the connection media. The connection is preferably designed to be flat so that only a small installation stroke or eccentric stroke is required.

The present invention further relates to a process for replacing a target in a coating plant as described above. In the process according to the invention, the pre-assembled unit of dark space shield, target and target backing plate is first detached from the remaining coating plant by operating the coupling mechanism. Subsequently, the pre-assembled unit of dark space shield, target and target backing plate is removed from the coating plant. Then, a new pre-assembled unit of dark space shield, target and target backing plate can be introduced into the coating plant and the pre-assembled unit can be attached to the remaining coating plant by operating the coupling mechanism.

Preferably, the coupling mechanism comprises an eccentric shaft, wherein detaching and attaching the pre-assembled unit is performed, preferably manually, by rotating an operating section of the eccentric shaft, preferably by a maximum of 330°, more preferably by a maximum of 180°.

In the following, preferred embodiments of the present invention are described in detail with reference to the Figures.

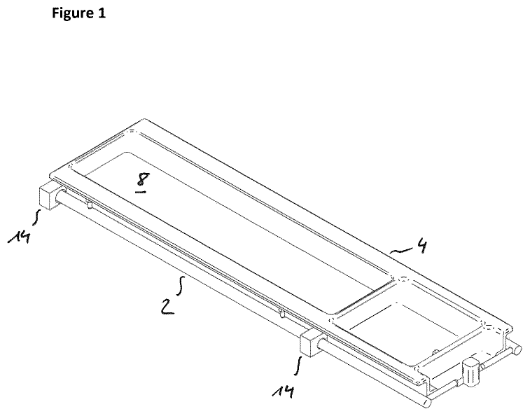

FIG. 1 shows: a perspective view of a section of a coating plant of the invention;

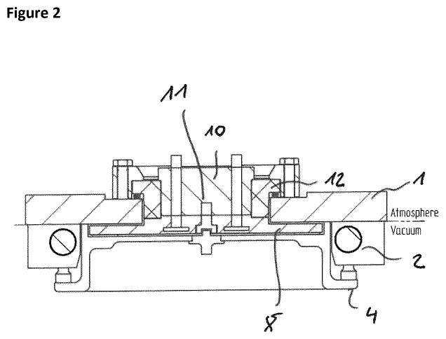

FIG. 2 shows: a cross-section through FIG. 1 (inverted);

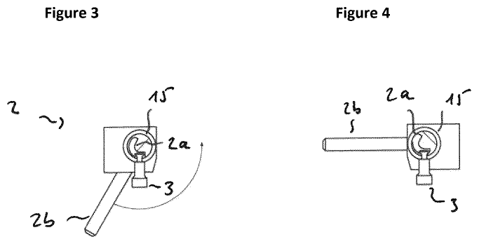

FIG. 3 shows: a schematic cross-section view illustrating the operating principle of the eccentric shaft;

FIG. 4 shows: a schematic cross-section view illustrating the operating principle of the eccentric shaft;

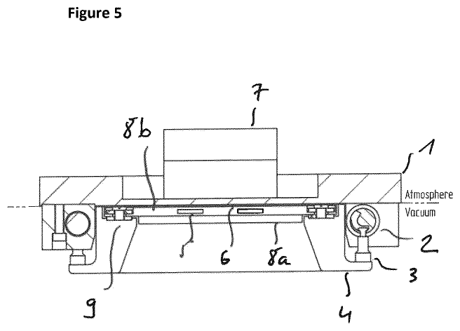

FIG. 5 shows: a cross-section through FIG. 1 (inverted); and

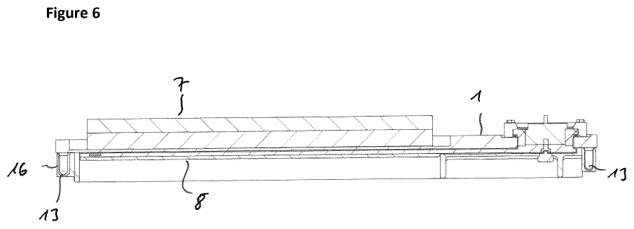

FIG. 6 shows: a longitudinal section through a section of a coating plant according to a particularly preferred embodiment.

FIG. 1 is a perspective view of a section of a coating plant according to a preferred embodiment of the present invention. FIGS. 2 and 5 show the corresponding cross-section views. FIGS. 1, 2 and 5 in particular show the pre-assembled unit of dark space shield 4, target 8a and target backing plate 8b of the invention. Target 8a and target backing plate 8b together form the cathode 8. According to the invention, this pre-assembled unit can be introduced as a unit into the coating plant and can be replaced as a unit, wherein the cathode 8 (consisting of target 8a and target backing plate 8b) and dark space shield 4 are electrically insulated from one another. The coating plant (not displayed as to the remaining parts) further comprises a coupling mechanism that allows the pre-assembled unit of dark space shield 4, target 8a and target backing plate 8b to be attached to a component of the coating plant, wherein said coupling mechanism can be fixed to the dark space shield 4 or interacts with the dark space shield 4. In the embodiment according to FIGS. 1, 2 and 5, said coupling mechanism comprises two eccentric shafts 2, which extend along the longitudinal extension of the pre-assembled unit. In the embodiment shown, said two eccentric shafts 2 are each rotatably mounted in bearing blocks 14.

The principle of said eccentric shafts 2 is illustrated schematically in FIGS. 3 and 4. The eccentric shaft 2 can be designed as a tube or as a round rod having one or more eccentrically formed inner sections 2a, wherein in each of the eccentrically formed inner sections 2a at least one opening for receiving a coupling element, for example a bolt 3, is provided. As shown in FIGS. 3 and 4, said bolts 3 can enter said openings so that, due to the eccentrically formed inner profile 2a, a rotation of the eccentric shaft 2 in direction of the arrow in FIG. 3 causes the bolts 3 to be drawn upwards in FIG. 3. Accordingly, in the embodiment according to FIGS. 1, 2 and 5, a corresponding rotation of the eccentric shaft 2 results in the pre-assembled unit of dark space shield 4, target 8a and target backing plate 8b being drawn radially towards the center/middle axis of the eccentric shaft, i.e. in the direction of the two bearing blocks 14.

As is clear from FIG. 6, showing the further components of the coating plant of the invention, this movement causes the pre-assembled unit of dark space shield 4, target 8a and target backing plate 8b to be pressed in direction of the magnet system 7 of the coating plant. In order to facilitate correct positioning of the pre-assembled unit with respect to the magnet system 7, positioning pins 13 are provided which can enter the corresponding positioning sleeves 16 in the preassembled unit.

The attachment of the pre-assembled unit to the coating plant is preferably carried out by manual rotation of the eccentric shafts 2, for example using the actuating element 2b (see FIGS. 3 and 4).

The cross-section of FIG. 5 again shows the positioning of the pre-assembled unit in relation to the magnet system 7. Moreover, cooling channels 5 for cooling the backing plate 8a as well as insulators 9 which electrically insulate the target 8a and the target backing plate 8b from the dark space shield 4 are shown.

FIG. 5 also represents part of the vacuum chamber 1 of the coating plant. As can be clearly seen, the chamber wall 6 of the vacuum chamber 1 extends between the magnet system 7 on the one hand and the pre-assembled unit consisting of the dark space shield 4, target 8a and target backing plate 8b on the other hand. In other words, the dashed line in FIG. 5 forms an imaginary dividing line between atmospheric pressure on the one hand and vacuum on the other hand. Thus, the coupling mechanism of the invention, i.e. in particular the eccentric shaft 2, is located within the vacuum in the processing area so that no additional openings are required. In other words, the entire target attachment, including eccentric shaft and actuating element, is located within the vacuum. In this way, vacuum leakages can be avoided. According to an alternative embodiment, it is possible that only the actuating element 2b of the eccentric shaft 2 extends into the area of atmospheric pressure. Clamping is performed outside the target area and does not reach into the processing chamber. Thus, sealing to the atmosphere is not necessary for the clamping mechanism and the impact on the magnetic field is reduced to a minimum.

FIG. 2 shows a cross-section view through the section of the coating plant which comprises the inlet 10 for the cooling medium as well as for the electric current. In particular, a mounting screw 11 and the insulators 12 for the power supply can be seen. Accordingly, the media connection block 10 for the media is located separately outside the processing area and is separated from the target 8a. The connection for the power and water supply, as well as the vacuum and atmospheric seal between the cathode and the chamber, is ensured with screw 11.

1. A coating plant for coating substrates by means of sputtering comprising at least a magnet system, a dark space shield, a target and a target backing plate, wherein the dark space shield, the target and the target backing plate form a pre-assembled unit which can be introduced as a unit into the coating plant and can be replaced as a unit, with target and dark space shield being electrically insulated from each other, wherein the coating plant further comprises a coupling mechanism that allows the pre-assembled unit to be attached to the coating plant and wherein the coupling mechanism is fixed to the dark space shield or interacts with the dark space shield.

2. The coating plant of claim 1, wherein the coupling mechanism comprises an eccentric shaft.

3. The coating plant of claim 2, wherein the eccentric shaft comprises a tube or a round rod having one or more eccentrically formed inner sections, wherein at least one opening for receiving a coupling element is provided at each of the eccentrically formed inner sections.

4. The coating plant of claim 2, wherein the dark space shield or a section of the coating plant to which the pre-assembled unit can be attached comprises one or more coupling elements which are adapted to engage with the eccentric shaft.

5. The coating plant of claim 2, wherein a rotation of the eccentric shaft causes the unit consisting of dark space shield, target and target backing plate to be moved towards the magnet system and to be held in a defined position.

6. The coating plant of claim 2, wherein the pre-assembled unit of dark space shield, target and target backing plate has a longitudinal extension and the eccentric shaft extends along said longitudinal extension.

7. The coating plant of claim 2, wherein the eccentric shaft allows a maximum stroke of 10 mm at most.

8. The coating plant of claim 2, wherein the eccentrical shaft can be directly manually rotated.

9. The coating plant of claim 1, wherein the coating plant comprises a vacuum area which is evacuated for a coating process and wherein the coupling mechanism is located entirely within the vacuum area.

10. The coating plant of claim 9, wherein the vacuum area has to be opened in order to allow manual operation of the coupling mechanism.

11. The coating plant of claim 1, wherein the dark space shield and the coupling mechanism are electrically insulated from the target.

12. The coating plant of claim 1, wherein the magnet system can be displaced with respect to the pre-assembled unit of dark space shield, target and target backing plate in three spatial directions.

13. The coating plant of claim 1, wherein the coating plant further comprises a connecting section via which electric current and/or a coolant can be supplied into the pre-assembled unit of dark space shield, target and target backing plate.

14. A process of replacing a target in a coating plant of claim 1, the process comprising:
detaching the pre-assembled unit of dark space shield, target and target backing plate from the remaining coating plant by operating the coupling mechanism;
removing the pre-assembled unit of dark space shield, target and target backing plate from the coating plant;
introducing a new pre-assembled unit of dark space shield, target and target backing plate into the coating plant; and
attaching the pre-assembled unit of dark space shield, target and target backing plate to the remaining coating plant by operating the coupling mechanism.

15. The process of claim 14, wherein the coupling mechanism comprises an eccentric shaft and wherein detaching and attaching the pre-assembled unit of dark space shield, target and target backing plate is performed by rotating an operating section of the eccentric shaft.

16. The coating plant of claim 12, wherein the magnet system can be tilted with respect to the pre-assembled unit of dark space shield, target and target backing plate.

17. The coating plant of claim 13, wherein at least one additional threaded connection is provided in the area of said connecting section.

18. The process of claim 15, wherein detaching and attaching the pre-assembled unit of dark space shield, target and target backing plate is performed by rotating the operating section of the eccentric shaft by a maximum of 330°.
